(19) United States
(12) Patent Application Publication
(10) Pub. No.: US 2022/0075464 A1
(43) Pub. Date: Mar. 10, 2022

(54) CASE FOR ELECTRONIC DEVICE

(71) Applicant: Samsung Electro-Mechanics Co., Ltd., Suwon-si (KR)

(72) Inventors: Joo Hyoung LEE, Suwon-si (KR); Joo Yul KO, Suwon-si (KR)

(73) Assignee: Samsung Electro-Mechanics Co., Ltd., Suwon-si (KR)

(21) Appl. No.: 17/167,305

(22) Filed: Feb. 4, 2021

(30) Foreign Application Priority Data
Sep. 10, 2020 (KR) 10-2020-0115984
Nov. 10, 2020 (KR) 10-2020-0149365

(51) Int. Cl. G06F 3/044; H05K 5/00; H05K 5/02

(52) U.S. Cl. CPC G06F 3/044; H05K 5/0217; H05K 5/0017

(57) ABSTRACT

A case for an electronic device comprising a touch member disposed at a side portion of the electronic device, and a touch sensing device disposed inside the electronic device is provided. The case includes a case body including a side portion and coupled to cover at least a part of an external surface of the electronic device; a conductor disposed in a first area of the side portion of the case body, and configured to face the touch member when the case is coupled to the electronic device, and a dielectric member disposed on one side of the conductor, where the conductor is comprised of a conductive material.

### CROSS-REFERENCE TO RELATED APPLICATION(S)

This application claims the benefit under 35 USC § 119(a) of Korean Patent Application No. 10-2020-0115984 filed on Sep. 10, 2020, and Korean Patent Application No. 10-2020-0149365 filed on Nov. 10, 2020 in the Korean Intellectual Property Office, the entire disclosures of which are incorporated herein by reference for all purposes.

### BACKGROUND

### 1. Field

The following description relates to a case for an electronic device.

### 2. Description of Related Art

Recently, wearable devices have been developed in a thin form factor, are simpler, and have been implemented with sleeker, more elegant designs. Thus, typical mechanical switches are being eliminated. Dustproof and waterproof technologies are being implemented, as well as the development of an integrated model with a smooth design.

Currently, technologies such as touch on metal (ToM) technology that implements touch inputs on metal, capacitor sensing technology using touch panels, micro-electro-mechanical-system (MEMS), and micro strain gauges are being developed. Furthermore, a force touch function is also being developed.

In the example of an existing mechanical switches, a large sized mechanical switch and a large internal space are needed to implement the function(s) of the switch. Thus, there may be a disadvantage that the exterior of the wearable device may not be sleek or elegant due to a shape protruding to the outside of an external case, or the structure not being integrated with the external case, and the wearable device may occupy a relatively large space. Additionally, there is a risk of electric shocks due to direct contact with a mechanical switch that is electrically connected and, in particular, there is a disadvantage that it may be difficult to obtain a waterproof and dustproof construction of the wearable device due to structural characteristics of the mechanical switch.

In order to solve this disadvantage, a touch sensing device having a touch sensing function replacing a mechanical switch has been developed.

However, typical cases have been manufactured without any consideration or additional function for the touch sensing function. When the typical cases are used in an electronic device having a touch sensing device, there may be problems in which they may not be recognized, or sensitivity may be reduced.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a case, for an electronic device including a touch member disposed at a side portion of the electronic device, and a touch sensing device disposed inside the electronic device, the case including a case body, comprising a non-conductive side portion, and configured to cover at least a part of an external surface of the electronic device; a conductor, disposed in a first area of the non-conductive side portion of the case body, and configured to face the touch member when the case is coupled to the electronic device; and a dielectric member disposed on one side of the conductor, wherein the conductor is comprised of a conductive material.

The conductor may be configured to generate parasitic capacitance between a user and the touch sensing device in response to a touch by the user.

The conductor may be completely embedded in the case body, and is disposed inside the non-conductive side portion of the case body.

The conductor may be disposed inside the non-conductive side portion of the case body, and is disposed to be exposed externally from at least one of an external portion of an internal portion of the non-conductive side portion of the case body and an internal portion of the non-conductive side portion of the case body.

The conductor may be disposed to be exposed externally from an external portion of the non-conductive side portion of the case body and an internal portion of the non-conductive side portion of the case body.

The conductor may be disposed on an external surface of the non-conductive side portion of the case body and an internal surface of the non-conductive side portion of the case body.

The dielectric member may be provided as a plurality of dielectric members, and the plurality of dielectric members may be respectively disposed on an outer surface of the conductor and an inner surface of the conductor.

The dielectric member may be disposed to surround the conductor.

The case may include a touch area display member disposed in a touch area in an external portion of the non-conductive side portion of the case body.

In a general aspect, a case, for an electronic device comprising a touch member disposed at a side portion of the electronic device, and a touch sensing device disposed inside the electronic device, the case includes a case body, including a dielectric side portion, and configured to cover at least a part of an external surface of the electronic device; and a conductor, disposed in a first area of the dielectric side portion of the case body, and configured to face the touch member when the case is coupled to the electronic device, wherein the conductor is comprised of a conductive material.

The conductor may be configured to generate parasitic capacitance between a user and the touch sensing device in in response to a touch by the user.

The conductor may be completely embedded in the case body, and may be disposed inside the dielectric side portion of the case body.

The conductor may be disposed inside the dielectric side portion of the case body, and may be disposed to be exposed externally from at least one of an external portion of the dielectric side portion of the case body and an internal portion of the dielectric side portion of the case body.

The conductor may be disposed on an outer surface of the dielectric side portion of the case body and an inner surface of the dielectric side portion of the case body.

The case may further include a touch area display member disposed in a touch area in an external portion of the dielectric side portion of the case body.

The parasitic capacitance may include an internal capacitance that is generated between the touch sensing device and the conductor, and an external capacitance that is generated between the conductor and the user.

Other features and aspects will be apparent from the following detailed description, the drawings, and the claims.

### BRIEF DESCRIPTION OF DRAWINGS

FIG. 1 illustrates an example case for an electronic device, in accordance with one or more embodiments.

FIG. 2 illustrates cross-sectional structures of an example electronic device and an example case for the electronic device.

FIG. 3 illustrates cross-sectional structures of an example electronic device and an example case for the electronic device.

FIG. 4 illustrates cross-sectional structures of an example electronic device and an example case for the electronic device.

FIG. 5 illustrates a conductor included in an example case for an example electronic device.

FIGS. 6A and 6B illustrate conductors included in example cases for an example electronic device.

FIG. 7 illustrates an example conductor included in an example case for an example electronic device.

FIG. 8 illustrates an example conductor included in an example case for an example electronic device.

FIGS. 9A and 9B illustrate example conductors included in an cases for an example electronic device.

FIG. 10 illustrates an example case for an example electronic device, having a conductor and a dielectric member.

FIG. 11 illustrates an example case for an example electronic device, having a conductor and a dielectric member.

FIG. 12 illustrates an example case for an example electronic device, having a conductor and a touch area display unit.

FIG. 13 illustrates an example case for an example electronic device, having a dielectric member and a conductor included in a case body.

FIGS. 14A and 14B illustrate example conductors included in example cases for an example electronic device.

FIG. 15 illustrates a dielectric member and a conductor included in an example case body.

FIG. 16 illustrates a dielectric member and a conductor included in an example case body.

FIG. 17 illustrates an example touch sensing circuit unit when no conductor is provided.

FIG. 18 illustrates an example touch sensing circuit unit when there is a conductor.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

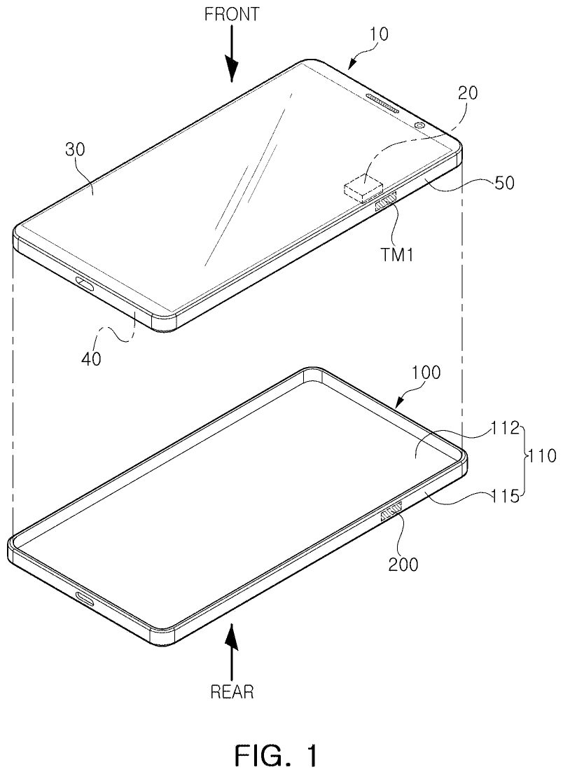

FIG. 1 illustrates an example case for an example electronic device, in accordance with one or more embodiments.

Referring to FIG. 1 to FIG. 3, an electronic device 10 (e.g., a mobile phone) to which the present disclosure is applied, may include a side portion 50 located between a front surface 30 and a rear surface 40, on which a display is disposed.

The side portion 50 of the electronic device 10 may include a touch member TM1, located at a segment or first area of the side portion 50. The electronic device 10 may further include a touch sensing device 20 that detects a touch to the touch member TM1, or senses the presence of a finger above the touch member TM1.

The side portion 50 may include, for example, a frame 51, a cover 52, and a glass 53. The frame 51 may extend from an inside, or inner, area of the electronic device 10 to the side portion 50. The cover 52 may extend from the rear surface 40 of the electronic device 10 to the side portion 50. The glass 53 may extend from the front surface 30 of the electronic device 10 to the side portion 50. Since this example may be only one example of the side portion 50, the present disclosure is not limited to this example. The side portion 50 may not be limited to a specific structure.

For example, the frame 51 may be, as a non-limiting example, a metal frame that forms a central skeleton of the electronic device 10. The cover 52 may be non-conductive, for example, a material of the cover 52 may be glass or plastic. The glass 53 may be a front display glass, and may not be limited to the above example.

In an example, the electronic device 10 may include a side portion 50 having a three-layer structure including a glass 53, a frame 51, and a cover 52. In another example, the side portion 50 of the electronic device 10 may have a two-layer structure of a frame 51 and a cover 52. In this example, the frame 51 may be disposed in a central portion of side portion 50 of the electronic device 10, and the cover 52 may be disposed below the central portion.

Referring to FIG. 1, to replace a typical mechanical button or switch, a touch member TM1, a portion of the side portion 50, may be disposed on the side portion 50.

In an example, the touch sensing device 20 may include a sensor that detects a touch to the touch member TM1, or that senses an object such as a finger above the touch member TM1, and may detect a touch by a contact, force, or a combination thereof, such as capacitive sensing, inductive sensing, ultrasonic sensing, and the like, but is not limited to a specific sensing manner. In this example, the combination of contact and force may be a hybrid sensing structure that performs both contact sensing and force sensing.

In an example, referring to FIG. 1, the electronic device 10 may be, as non-limiting examples, a portable device, such as, but not limited to, a smartphone, or a wearable device, such as a smartwatch, but is not limited to a specific device, and may be a portable or wearable electronic device, or an electronic device having a switch for operation control.

In the examples, the touch may include a touch corresponding to a contact, and a touch corresponding to pressing. In this example, the contact may refer to a simple contact that may not be accompanied by a pressing force, and the pressing may refer to force of pressing, following the contact. Therefore, in the examples, in a similar manner to the contact or the force, if not limited to a specific term, the touch may refer to concepts including both contact and force (e.g., pressing force), or may refer to any either thereof.

In an example, referring to FIG. 1, the electronic device 10 may be a portable device, such as a smartphone, or a wearable device, such as a smartwatch, but is not limited to a specific device, and may be a portable or wearable electronic device, or an electronic device having a switch for operation control.

The touch member TM1, illustrated in FIG. 1, may not be exposed externally, and in particular, the touch member may have a structure that may not be seen externally by various passivation treatments.

Although FIG. 1 illustrates that one (1) touch member TM1 is included, this is only an example. The electronic device may actually include at least one touch member, which is illustrative, but is not limited thereto.

A case 100 for an electronic device, in accordance with one or more embodiments, may be applied to the electronic device 10 described above, but is not limited to the electronic device described above. The case 100 may be applied to an electronic device having a touch sensing device.

The case 100 may include, for example, only a side portion 115. As another example, the case 100 may include a bottom portion 112 and a side portion 115, which are non-conductive.

In an example, the case 100 may further include a conductor 200 disposed on the side portion 115, and a detailed description thereof will be provided later.

For each of the drawings of the present disclosure, unnecessary duplicate descriptions may be omitted for the same reference numerals and components having the same functions, and possible differences for each of the drawings may be described.

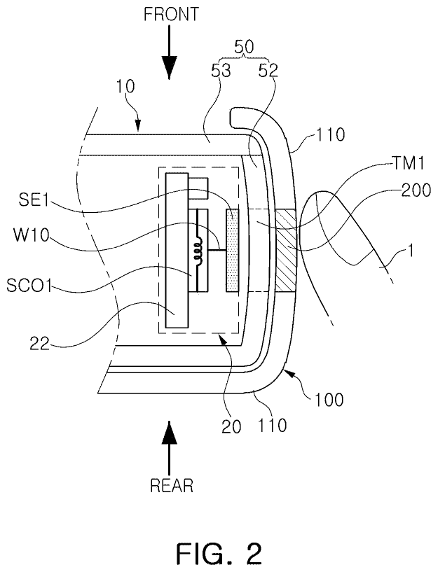

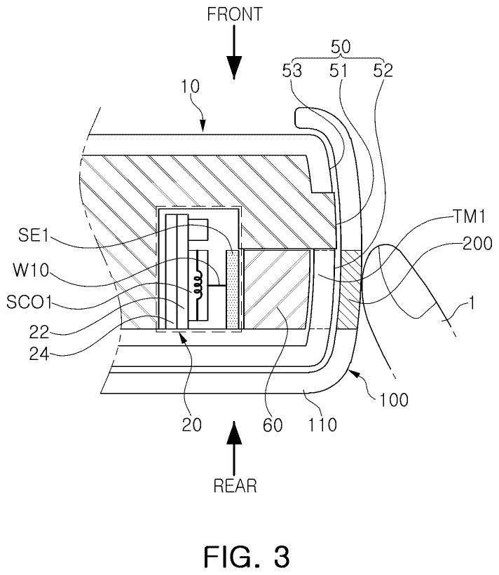

FIG. 2 illustrates cross-sectional structures of an example electronic device and an example case for the electronic device, and FIG. 3 illustrates cross-sectional structures of an example electronic device and an example case for the electronic device.

Referring to FIGS. 2 and 3, a case 100 for an electronic device, in accordance with one or more embodiments, may be applied to the electronic device 10 described above.

The case 100 may include a case body 110, a conductor 200, and a dielectric member 300 (FIGS. 9A and 9B).

The case body 110 may include a bottom portion 112 (FIG. 1) and a side portion 115 (FIG. 1), which may be non-conductive, and may be coupled to cover a portion of an external portion (e.g., the side portion 50 and the rear surface 40) of the electronic device 10.

The conductor 200 may be disposed in a portion of the side portion 115 of the case body 110 facing a touch member TM1 of the electronic device 10 when coupled to the electronic device 10, and may be formed of an electrically conductive material or may include a conductive material.

The dielectric member 300 will be described with reference to FIGS. 9A and 9B.

Referring to FIG. 2, the electronic device 10 may include a touch sensing device 20 that detects a touch to the touch member TM1, or that senses the presence of an object such as a finger above the touch member TM1. The touch sensing device 20 may include a sensing electrode SE1, a conductor wiring W10, a sensing coil SCO1, and a substrate 22.

The sensing electrode SE1 may be made of a conductive material, and may be disposed inside or may be spaced apart inside the touch member TM1, and may react with the conductor 200 to form capacitance. The conductor wiring W10 may be made of a conductive material, and may electrically connect the sensing electrode SE1 and the sensing coil SCO1. The sensing coil SCO1 may be disposed on the substrate 22, and may be connected to the sensing electrode SE1 through the conductor wiring W10. The substrate 22 may be disposed directly on a frame in the electronic device 10 or may be disposed via a plate.

The touch sensing device 20 embedded in the electronic device 10 is not limited to the above-described structure, and may have a structure sufficiently capable of sensing a touch.

In another example, referring to FIG. 3, the electronic device 10 may include a touch sensing device 20 that detects a touch to the touch member TM1, or that senses the presence of an object such as a finger above the touch member TM1.

As a difference from the structure illustrated in FIG. 2, the electronic device 10 may further include a dielectric member 60 disposed inside or spaced apart inside the touch member TM1. The touch sensing device 20 may be disposed inside or spaced apart inside the dielectric member 60.

In the examples, the dielectric member 60 may be a member disposed on a portion of the frame 51 to have predetermined degree of permittivity, and may be, for example, Glastic, a material made from glass and plastic. This is not limited to the above example as long as the member has permittivity that generates parasitic capacitance by touching a human body.

The touch sensing device 20 of the electronic device 10, illustrated in FIG. 2, may perform an operation according to a touch, when a user 1 (e.g., a user's hand or finger) touches the touch member TM1, a side button. In the electronic device 10, there may be problems in that touch sensitivity may be deteriorated and an operation according to the touch may not be performed, when a typical case (or a protective case) for an electronic device is covered, or the user wears a general glove.

This may be described using Equation 1 below.

C=[εA]/d Equation 1:

In Equation 1, C is capacitance [F] between parallel plates, ε is permittivity [F/m] between the parallel plates, A is an area [m²] of the parallel plates, and d is a distance [m] between the parallel plates. In the electronic device 10, the parallel plates may be the user's hand and the sensing electrode SE1.

In Equation 1, d may be a distance between the user's hand and the sensing electrode SE1. In this example, it can be seen that the longer the distance d, the lower a value of the capacitance C. In an example, when the distance d is a certain distance or more, the capacitance C may be about zero (0), such that a signal may not be detected in a capacitive sensing operation.

In consideration of these drawbacks, to overcome the distance d, a method of thinning a case for an electronic device to shorten the distance d should be used. In this regard, since a natural function of the case, e.g., a protection function of shock absorption may cause loss, it may not be desirable to use a method of thinning the case to a certain level or less.

Therefore, in the examples, to improve sensitivity (sensing ability) sufficiently to detect a signal by a touch without thinning the case, a configuration in which the conductor 200 is disposed on the side portion 115 of the case 100 facing the touch member TM1 disposed on the side portion 50 of the electronic device 10 may be proposed, which will be described later.

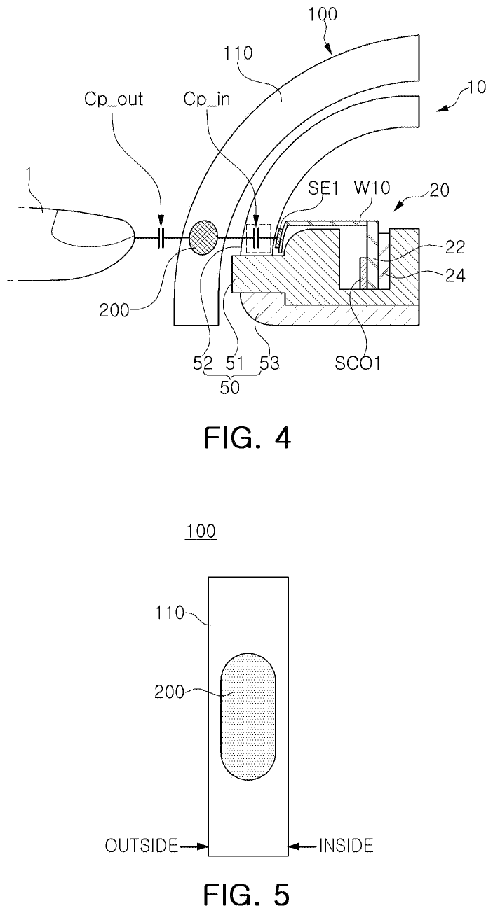

FIG. 4 illustrates cross-sectional structures of an example electronic device and an example case for the electronic device.

Referring to FIG. 4, a conductor 200 may generate parasitic capacitance Cp_out between a user 1 and a touch sensing device 20 in response to a touching by the user.

Additionally, a case 100 for an electronic device may be located between the user 1 and a sensing electrode SE1 having conductivity, and may include the conductor 200 disposed on a side portion 115 of the case 100 facing the sensing electrode SE1.

Therefore, internal capacitance Cp_in may be generated between the sensing electrode SE1 inside the electronic device 10 and the conductor 200 of the case 100, and outer capacitance Cp_out may be generated between the conductor 200 of the case 100 and the user 1 (e.g., a hand or finger).

Accordingly, as the internal capacitance Cp_in and the outer capacitance Cp_out are generated, the distance d may be overcome even when the case 100 is used. Additionally, when the conductor 200 of the case 100 is touched, the same effect may be obtained, as compared to when the user (e.g., a hand or a finger) directly touches the touch member TM1 disposed on the side portion 50 of the electronic device 10.

Hereinafter, some examples in which a case 100 for an electronic device includes a conductor 200 will be described with reference to FIGS. 5, 6A, 6B, 7, and 8.

FIG. 5 illustrates a conductor included in a case for an electronic device, in accordance with one or more embodiments.

Referring to FIG. 5, a conductor 200 may not be exposed externally, and may be embedded in a side portion 115 of a case body 110.

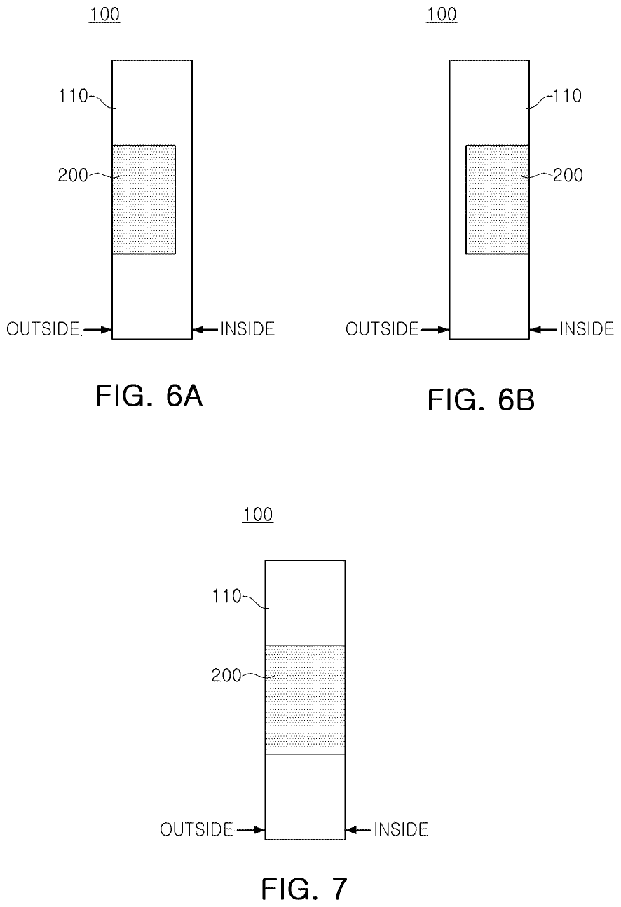

FIGS. 6A and 6B illustrate example conductors included in example cases for an electronic device, in accordance with one or more embodiments.

Referring to FIG. 6A, a conductor 200 may be disposed inside a side portion 115 of a case body 110, and may be disposed to be exposed externally outside the side portion 115 of the case body 110.

Referring to FIG. 6B, a conductor 200 may be disposed inside a side portion 115 of a case body 110, and may be disposed to be exposed externally inside the side portion 115 of the case body 110.

FIG. 7 illustrates an example conductor included in an example case for an electronic device, in accordance with one or more embodiments.

Referring to FIG. 7, a conductor 200 may be disposed to be exposed externally inside and outside a side portion 115 of a case body 110.

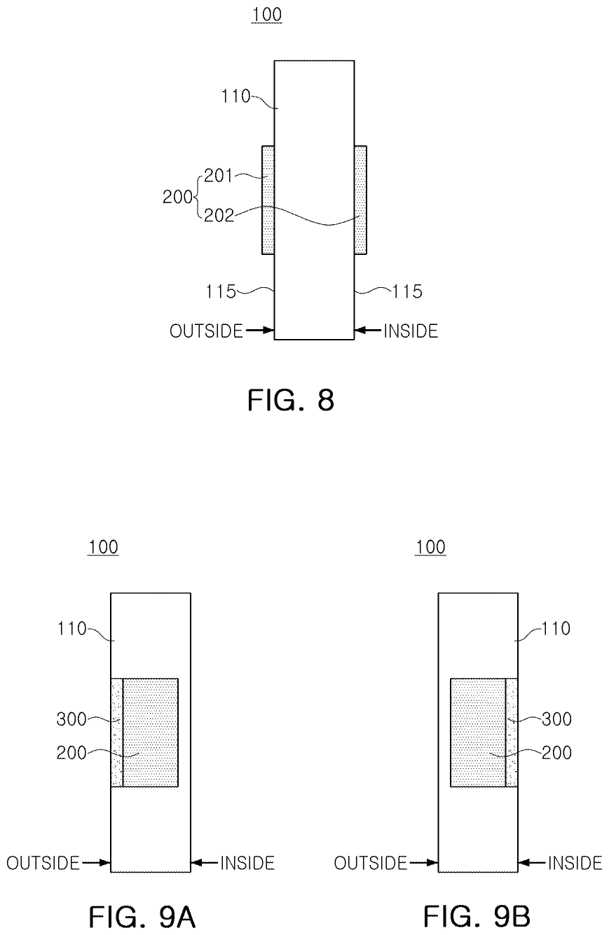

FIG. 8 illustrates an example conductor included in an example case for an electronic device, in accordance with one or more embodiments.

Referring to FIG. 8, a conductor 200 may be provided as a plurality of conductors 200, and the plurality of conductors 200 may be disposed inside and outside of a side portion 115 of a case body 110.

Additionally, the plurality of conductors 200 may include a first conductor 201 disposed on the outer surface of the side portion 115 of the case body 110, and a second conductor 202 disposed on the inner surface of the side portion 115 of the case body 110.

Referring to FIGS. 5 to 8, a main concept of the present disclosure may be provided to dispose the conductor 200 disposed on the case body 110 of the case 100, to improve touch sensing sensitivity.

Considering the main concept of the present disclosure, the present disclosure may be provided to dispose the conductive body 200 having conductivity inside, outside, or around the case 100, to obtain the same effect, even when the touch member of the electronic device (e.g., a mobile phone) covered with the case 100 is touched by the user (e.g., a hand), as compared to when directly touching the touch member of the electronic device without a case for an electronic device.

Referring to Equation 1, it can be seen that the capacitance C may be proportional to the permittivity c.

Additionally, when the case 100 to be used in the electronic device 10 (e.g., a mobile phone) includes the conductor 200 as illustrated in FIGS. 5 to 8, capacitance may increase.

Additionally, even when a dielectric member composed of a material having a high permittivity c is included, it may be helpful to increase the capacitance C, which will be described later.

FIGS. 9A and 9B illustrate example conductors included in example cases for an electronic device, in accordance with one or more embodiments.

Referring to FIGS. 9A and 9B, example cases 100 for an electronic device may further include a dielectric member 300 disposed on one side surface of a conductor 200.

Referring to FIG. 9A, the case 100 may further include the dielectric member 300 disposed on an outer surface of the conductor 200. Referring to FIG. 9B, the case 100 may further include the dielectric member 300 disposed on an inner surface of the conductor 200.

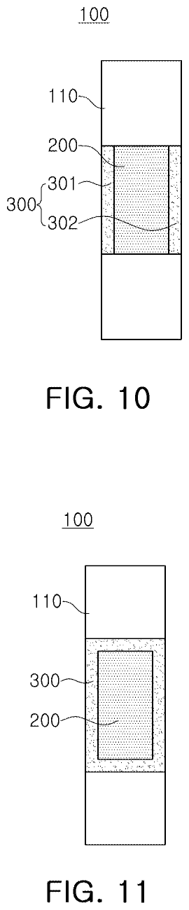

FIG. 10 illustrates an example case for an electronic device, having a conductor and a dielectric member, in accordance with one or more embodiments.

Referring to FIG. 10, a dielectric member 300 may be disposed on both surfaces of a conductor 200 including an outer surface and an inner surface.

Additionally, the dielectric member 300 may include a first dielectric 301 disposed on the outer surface of the conductor 200, and a second dielectric 302 disposed on the inner surface of the conductor 200.

FIG. 11 illustrates an example case for an electronic device, having a conductor and a dielectric member, in accordance with one or more embodiments.

Referring to FIG. 11, a dielectric member 300 may be disposed to surround a conductive member 200.

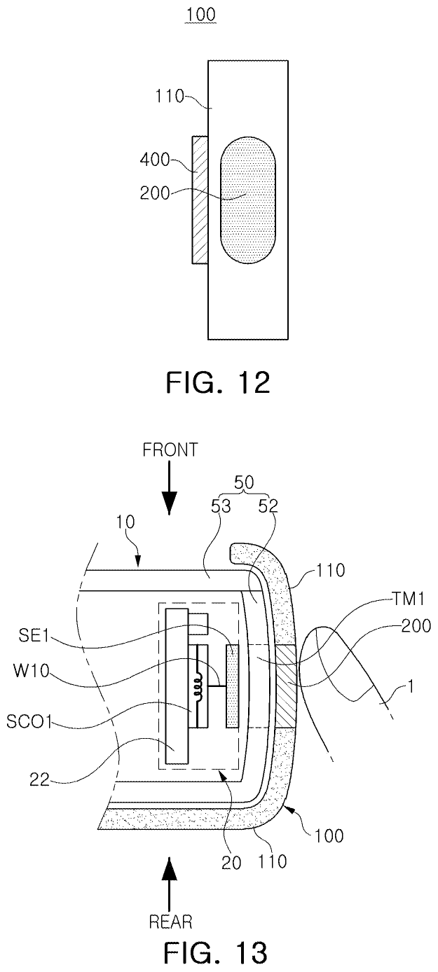

FIG. 12 illustrates an example case for an example electronic device, having a conductive member and a touch area display unit, in accordance with one or more embodiments.

Referring to FIG. 12, a case 100 for an electronic device may further include a touch area display member 400 disposed in a touch area in an external portion of a side portion 115 of a case body 110.

Additionally, when the case 100 of the present disclosure includes a conductive member 200 embedded in the case body 110, to easily grasp arrangement of the embedded conductive member 200, the case 100 may include the touch area display member 400 disposed on a surface of the case body 110.

Further, when the case 100 of an electronic device (e.g., a mobile phone) includes the conductive member 200 disposed inside the case body 110 not to be exposed externally, the touch area display member 400 may be additionally included in a portion to be touched. In this example, an area to be touched may be accurately recognized even when covered with the case 100.

In an example, the touch area display member 400 may be implemented with a simple picture or pattern, may have a protruding structure, and may itself be formed of at least one of a conductive member or a dielectric member.

FIG. 13 illustrates an example case for an electronic device, having a dielectric member and a conductive member included in a case body, in accordance with one or more embodiments.

Referring to FIG. 13, and, in comparison with the example illustrated in FIGS. 2 to 12, the cases illustrated in FIGS. 2 to 12 include the side portion 115 that may be non-conductive, while a case 100 illustrated in FIG. 13 may include a side portion 115 that may be dielectric. Descriptions overlapping the above descriptions may be omitted.

Additionally, in differences between the case 100 illustrated in FIG. 5 and the case 100 illustrated in FIG. 13, the side portion 115 of the case illustrated in FIG. 5 may be non-conductive, while the side portion 115 of the case illustrated in FIG. 13 may be dielectric.

Even in this case, a conductive member 200 may generate parasitic capacitance Cp_out between a user 1 and a touch sensing device 20 in when touched by the user, as illustrated in FIG. 4.

Additionally, referring to FIG. 13, for example, the conductive member 200 may not be exposed externally, and may be embedded in the side portion 115 of a case body 110.

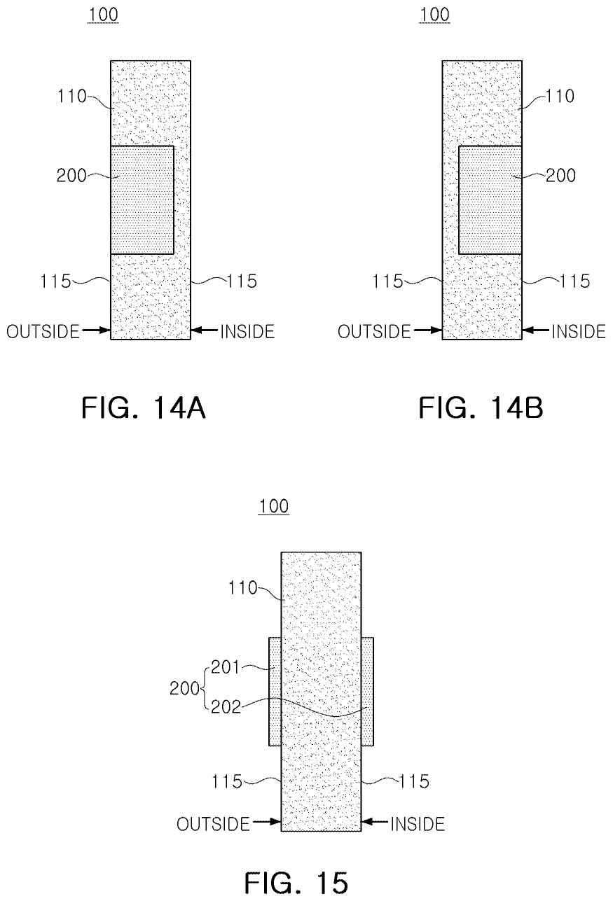

FIGS. 14A and 14B illustrate example conductive members included in example cases for an electronic device, in accordance with one or more embodiments.

Referring to FIGS. 14A and 14B, a conductive member 200 may be disposed inside a side portion 115 of a case body 110, and may be disposed to be exposed externally at least one of outside and inside the side portion 115 of the case body 110.

Referring to FIG. 14A, the conductive member 200 may be disposed inside the side portion 115 of the case body 110, and may be disposed to be exposed externally outside the side portion 115 of the case body 110.

Referring to FIG. 14B, the conductive member 200 may be disposed inside the side portion 115 of the case body 110, and may be disposed to be exposed externally inside the side portion 115 of the case body 110.

FIG. 15 illustrates a dielectric member and a conductive member included in a case body, in accordance with one or more embodiments.

Referring to FIG. 15, a conductive member 200 may be provided as a plurality of conductive members 200, and the plurality of conductive members 200 may be disposed on outer and inner surfaces of a side portion 115 of a case body 110.

In other words, the plurality of conductive members 200 may include a first conductive member 201 disposed on the outer surface of the side portion 115 of the case body 110, and a second conductive member 202 disposed on the inner surface of the side portion 115 of the case body 110.

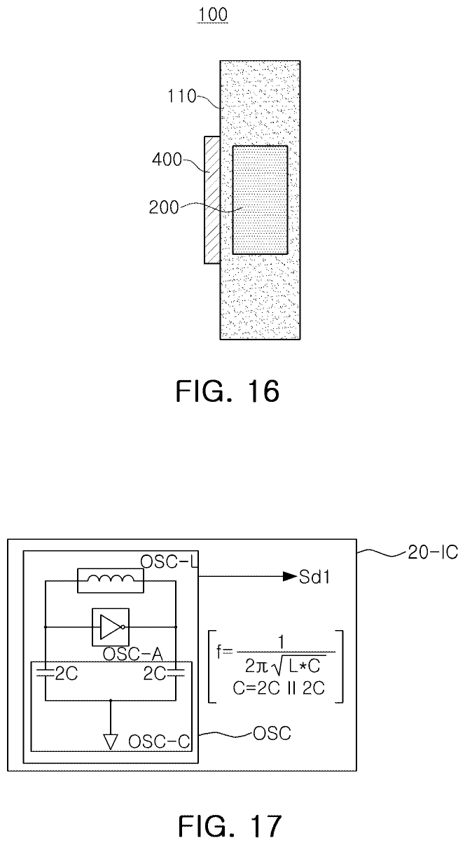

FIG. 16 illustrates a dielectric member and a conductive member included in a case body, in accordance with one or more embodiments.

Referring to FIG. 16, a case 100 for an electronic device may further include a touch area display member 400 disposed in a touch area in an external portion of a side portion 115 of a case body 110.

In an example, the touch area display member 400 may be implemented with a simple picture or pattern, may have a protruding structure, and may itself be formed of at least one of a conductive member or a dielectric member.

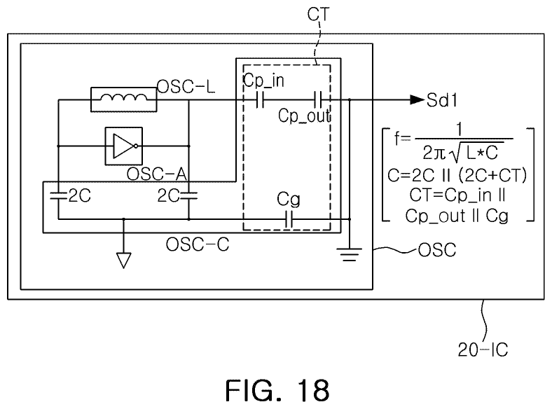

FIG. 17 illustrates an example touch sensing circuit unit when a conductor is not provided, and FIG. 18 illustrates an example touch sensing circuit unit when there is a conductor.

Referring to FIG. 17, when a conductor is not provided, since a typical case for an electronic device may be relatively thick, parasitic capacitance may be about zero (0) even when touched by a hand.

Referring to FIG. 18, when there is a conductor in a case for an electronic device, parasitic capacitance may be generated when touched. Such a change in capacitance may be detected using a frequency, to sense capacitance.

Referring to FIGS. 17 and 18, a circuit unit 20-IC may include an oscillation circuit OSC that generates oscillation signals having different resonance frequencies, depending on whether or not a touch member TM1 is touched.

In an example, the oscillation circuit OSC may include an inductance circuit OSC-L including a sensing coil SCO1, a capacitance circuit OSC-C including a capacitor element mounted on a substrate 22, and an amplification circuit OSC-A maintaining resonance.

The amplification circuit OSC-A is not limited to the function of amplification. In an example, the amplification circuit OSC-A may be an inverter or an amplifier.

Additionally, the amplification circuit OSC-A may generate a negative resistance such that a resonance circuit maintains and oscillates the resonance, to generate an oscillation signal having a corresponding resonance frequency.

Referring to FIG. 17, in an example where a case for an electronic device does not include a conductor, even when a user 1 (e.g., a hand or a finger) touches a touch member TM1, parasitic capacitance may not be generated. In this example, the inductance circuit OSC-L may provide inductance L, and the capacitance circuit OSC-C may provide capacitance C (where, C=2C∥2C). In this example, a resonance frequency may be expressed as Equation 2 below.

f=1/[2π*sqrt(L*C)] Equation 2:

where C=2C∥2C

Referring to FIG. 18, in an example where a case for an electronic device includes a conductor 200, when a user 1 (e.g., a hand or a finger) touches a touch member TM1, parasitic capacitance Cp_out and Cp_in may be generated. In this example, the inductance circuit OSC-L may provide inductance L, and the capacitance circuit OSC-C may provide capacitance C (where, C=2C II (2C+CT)) that may be varied by the parasitic capacitance. In this case, a resonance frequency may be expressed as Equation 3 below.

f=1/[2π*sqrt(L*C)] Equation 3:

where, C≈2C∥(2C+CT), and CT≈(Cp_in∥Cp_out∥Cg)

Referring to FIG. 18, when the user 1 (e.g., a hand or a finger) touches the case 100 including the conductor 200, such a touch may activate the touch member TM1. In this example, parasitic capacitance Cp_in and Cp_out may be generated between a first sensing electrode SE1 covered by a cover 52 and the user via the conductor 200 of the case 100, and magnitude of equivalent capacitance C of the oscillation circuit OSC may be changed by parasitic capacitance.

As a result, for example, referring to Equation 3, capacitance may increase to decrease a resonance frequency. This may be sensed to recognize the touch.

The oscillation circuit OSC illustrated in FIG. 18 may further include parasitic capacitance Cp_in and Cp_out and ground return capacitance Cg, in addition to the oscillation circuit OSC illustrated in FIG. 17.

Therefore, the oscillation circuit OSC of FIG. 18 may generate an oscillating signal having a frequency variable by the added parasitic capacitance Cp_in and Cp_out and the added ground return capacitance Cg, as the case 100 including the conductor 200 is touched.

In Equations 1 and 2, may mean that they may be the same or may be similar. In this case, ‘similar’ may refer to the act that other values may be further included.

In Equation 2, if “∥” is defined as follows, ‘a∥b’ may refer to a series connection of ‘a’ and ‘b’ in a circuit, and the sum thereof may be defined as calculated as ‘(a*b)/(a+b).’ This definition may also be applied to other Equations of the present disclosure.

In Equation 2, Cp_in may refer to parasitic capacitance between the user 1 and the conductor 200, Cp_out may refer to parasitic capacitance between the conductor 200 and the sensing electrode SE1, and Cg may refer to ground return capacitance between a circuit ground and earth.

Comparing Equation 2 (in the example where a conductor is not provided) and Equation 3 (in the example where a conductor is provided), since capacitance 2C of Equation 2 may be increased to capacitance (2C+CT) of Equation 3, it can be seen that a resonance frequency without a touch may be lowered to a resonance frequency with a touch.

According to an embodiment of the present disclosure, a case for an electronic device, that may be applied to the electronic device having a touch sensing device without a physical button, instead of a typical mechanical button, may have an advantage to improve sensitivity of touch sensing such as capacitive sensing or/and inductive sensing.

While this disclosure includes specific examples, it will be apparent after an understanding of the disclosure of this application that various changes in forms and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A case, for an electronic device comprising a touch member disposed at a side portion of the electronic device, and a touch sensing device disposed inside the electronic device, the case comprising:
a case body, comprising a non-conductive side portion, and configured to cover at least a part of an external surface of the electronic device;
a conductor, disposed in a first area of the non-conductive side portion of the case body, and configured to face the touch member when the case is coupled to the electronic device; and
a dielectric member disposed on one side of the conductor,
wherein the conductor is comprised of a conductive material.

2. The case according to claim 1, wherein the conductor is configured to generate parasitic capacitance between a user and the touch sensing device in response to a touch by the user.

3. The case according to claim 1, wherein the conductor is completely embedded in the case body, and is disposed inside the non-conductive side portion of the case body.

4. The case according to claim 1, wherein the conductor is disposed inside the non-conductive side portion of the case body, and is disposed to be exposed externally from at least one of an external portion of an internal portion of the non-conductive side portion of the case body and an internal portion of the non-conductive side portion of the case body.

5. The case according to claim 1, wherein the conductor is disposed to be exposed externally from an external portion of the non-conductive side portion of the case body and an internal portion of the non-conductive side portion of the case body.

6. The case according to claim 1, wherein the conductor is disposed on an external surface of the non-conductive side portion of the case body and an internal surface of the non-conductive side portion of the case body.

7. The case according to claim 1, wherein the dielectric member is provided as a plurality of dielectric members, and the plurality of dielectric members are respectively disposed on an outer surface of the conductor and an inner surface of the conductor.

8. The case according to claim 1, wherein the dielectric member is disposed to surround the conductor.

9. The case according to claim 1, further comprising a touch area display member disposed in a touch area in an external portion of the non-conductive side portion of the case body.

10. A case, for an electronic device comprising a touch member disposed at a side portion of the electronic device, and a touch sensing device disposed inside the electronic device, the case comprising:
a case body, comprising a dielectric side portion, and configured to cover at least a part of an external surface of the electronic device; and
a conductor, disposed in a first area of the dielectric side portion of the case body, and configured to face the touch member when the case is coupled to the electronic device,
wherein the conductor is comprised of a conductive material.

11. The case according to claim 10, wherein the conductor is configured to generate parasitic capacitance between a user and the touch sensing device in in response to a touch by the user.

12. The case according to claim 10, wherein the conductor is completely embedded in the case body, and is disposed inside the dielectric side portion of the case body.

13. The case according to claim 10, wherein the conductor is disposed inside the dielectric side portion of the case body, and is disposed to be exposed externally from at least one of an external portion of the dielectric side portion of the case body and an internal portion of the dielectric side portion of the case body.

14. The case according to claim 10, wherein the conductor is disposed on an outer surface of the dielectric side portion of the case body and an inner surface of the dielectric side portion of the case body.

15. The case according to claim 10, further comprising a touch area display member disposed in a touch area in an external portion of the dielectric side portion of the case body.

16. The case according to claim 11, wherein the parasitic capacitance comprises an internal capacitance that is generated between the touch sensing device and the conductor, and an external capacitance that is generated between the conductor and the user.
